(19) United States
(12) Patent Application Publication
(10) Pub. No.: US 2024/0196647 A1
(43) Pub. Date: Jun. 13, 2024

(54) DISPLAY DEVICE MANUFACTURING METHOD

(71) Applicant: Japan Display Inc., Tokyo (JP)

(72) Inventor: Shinichi KAWAMURA, Tokyo (JP)

(73) Assignee: Japan Display Inc., Tokyo (JP)

(21) Appl. No.: 18/534,714

(22) Filed: Dec. 11, 2023

(30) Foreign Application Priority Data
Dec. 13, 2022 (JP) 2022-198576

(51) Int. Cl. H10K 59/12; H10K 71/10; H10K 71/20; H10K 71/60

(52) U.S. Cl. CPC H10K 59/1201; H10K 71/10; H10K 71/231; H10K 71/60

(57) ABSTRACT

According to one embodiment, a manufacturing method includes forming a lower electrode, forming a rib, and forming a partition including a conductive bottom portion, an insulating stem portion, and a top portion. The formation of the partition includes forming a first layer including a layer of a conductive first material, forming a second layer including a layer of an insulating second material, forming a third layer including a layer of a third material, forming the top, stem and bottom portions by first to third etching processes, respectively. An etching rate of the third material in the second etching process is lower than an etching rate of the second material in the second etching process.

### CROSS-REFERENCE TO RELATED APPLICATIONS

This application is based upon and claims the benefit of priority from Japanese Patent Application No. 2022-198576, filed Dec. 13, 2022, the entire contents of which are incorporated herein by reference.

### FIELD

Embodiments described herein relate generally to a manufacturing method of a display device.

### BACKGROUND

Recently, a display device with an organic light-emitting diode (OLED) applied thereto as a display element has been put into practical use. This display element comprises a lower electrode, an organic layer which covers the lower electrode, and an upper electrode which covers the organic layer.

Various lines such as a line for supplying power to the upper electrode are formed in a display area on which a plurality of display elements are arranged. A resistance due to these lines needs to be adjusted to a proper value, but such adjustment is not necessarily easy in some cases due to the structures of the display elements or surrounding thereof.

### BRIEF DESCRIPTION OF THE DRAWINGS

FIG. 1 is a diagram showing a configuration example of a display device according to an embodiment.

FIG. 2 is a schematic plan view showing an example of a layout of sub-pixels.

FIG. 3 is a schematic cross-sectional view of the display device along the III-III line of FIG. 2.

FIG. 4 is a schematic cross-sectional view showing an example of a configuration of a structure which can be applied to a partition.

FIG. 5 is a flowchart showing an example of the method of manufacturing a display device.

FIG. 6 is a schematic cross-sectional view showing a process in the method of manufacturing the display device.

FIG. 7 is a schematic cross-sectional view showing a process following FIG. 6.

FIG. 8 is a schematic cross-sectional view showing a process following FIG. 7.

FIG. 9 is a schematic cross-sectional view showing a process following FIG. 8.

FIG. 10 is a schematic cross-sectional view showing a process following FIG. 9.

FIG. 11 is a schematic cross-sectional view showing a process following FIG. 10.

FIG. 12 is a schematic cross-sectional view showing a process following FIG. 11.

FIG. 13 is a schematic cross-sectional view showing a process following FIG. 12.

FIG. 14 is a schematic cross-sectional view showing a process following FIG. 13.

FIG. 15 is a schematic cross-sectional view showing a process following FIG. 14.

FIG. 16 is a schematic cross-sectional view showing a process following FIG. 15.

FIG. 17 is a schematic cross-sectional view showing a process following FIG. 16.

FIG. 18 is a schematic cross-sectional view showing a process following FIG. 17.

FIG. 19 is a schematic view showing an example of how the display device is used.

FIG. 20 is a diagram showing a partition according to example 1.

FIG. 21 is a diagram showing a partition according to example 2.

FIG. 22 is a diagram showing a partition according to example 3.

### DETAILED DESCRIPTION

In general, according to the embodiments, a method of manufacturing a display device includes forming a lower electrode, forming a rib covering at least a part of the lower electrode, and forming a partition on the rib, the partition including a conductive bottom portion, an insulating stem portion located on the bottom portion, and a top portion located on the stem portion and protruding relative to side surfaces of the stem portion.

According to one viewpoint of the embodiments, formation of the partition includes forming a first layer including a layer formed of a conductive first material, forming a second layer including a layer formed of an insulating second material on the first layer, forming a third layer including a layer formed of a third material on the second layer, forming the top portion by patterning the third layer by a first etching process, forming the stem portion by patterning the second layer by a second etching process, and forming the bottom portion by patterning the first layer by a third etching process. Further, an etching rate of the third material in the second etching process is lower than an etching rate of the second material in the second etching process.

According to another viewpoint of the embodiments, formation of the partition includes forming a first layer including a layer formed of a conductive first material, forming a second layer including a layer formed of an insulating second material on the first layer, forming a third layer including a layer formed of a third material on the second layer, forming the top portion by patterning the third layer by a first etching process, forming the stem portion by patterning the second layer by a second etching process, and forming the bottom portion by patterning the first layer by a third etching process. Further, an etching rate of the third material in the third etching process is lower than the etching rate of the first material in the third etching process.

According to yet another viewpoint of the embodiments, formation of the partition includes forming a first layer including a layer formed of a conductive first material, forming a second layer including a layer formed of an insulating second material on the first layer, forming a third layer including a layer formed of the first material on the second layer, forming the top portion by patterning the third layer by a first etching process, forming the stem portion by patterning the second layer by a second etching process, and forming the bottom portion by patterning the first layer by a third etching process. Further, the layer formed of the first material included in the third layer is formed to be thicker than the layer formed of the first material included in the first layer.

According to these methods of manufacturing, a display device in which resistance of lines is improved can be provided.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. The third direction Z is a normal to a plane including the first direction X and the second direction Y. In addition, viewing various elements parallel to the third direction Z is referred to as plan view.

The display device of each of the embodiments is an organic electroluminescent display device comprising an organic light emitting diode (OLED) as a display element, and can be mounted on various types of electronic apparatuses such as televisions, personal computers, vehicle-mounted devices, tablet terminals, smartphones, cell phone terminals, wearable terminals, and the like.

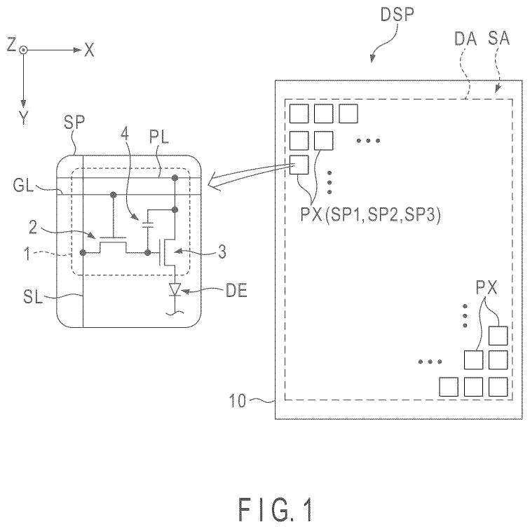

FIG. 1 is a diagram showing a configuration example of a display device DSP according to the present embodiment. The display device DSP includes a display area DA where images are displayed and a surrounding area SA around the display area DA, on an insulating substrate 10. The substrate 10 may be glass or a flexible resin film.

In the present embodiment, the shape of the substrate 10 in plan view is a rectangular shape. However, the shape of the substrate 10 in plan view is not limited to a rectangular shape, but may be any other shape such as a square, a circle, or an ellipse.

The display area DA includes a plurality of pixels PX arrayed in a matrix in the first direction X and the second direction Y. Each of the pixels PX includes a plurality of sub-pixels SP. As an example, each of the pixels PX includes a blue sub-pixel SP1, a green sub-pixel SP2, and a red sub-pixel SP3. Each of the pixels PX may include sub-pixels SP of other colors such as a white color together with the sub-pixels SP1, SP2, and SP3 or instead of any of the sub-pixels SP1, SP2, and SP3.

The sub-pixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL, and the other is connected to a gate electrode of the drive transistor 3 and the capacitor 4. In the drive transistor 3, one of the source electrode and the drain electrode is connected to a power line PL and the capacitor 4, and the other is connected to the display element DE.

Incidentally, the configuration of the pixel circuit 1 is not limited to the example shown in the figure. For example, the pixel circuit 1 may comprise more thin-film transistors and more capacitors.

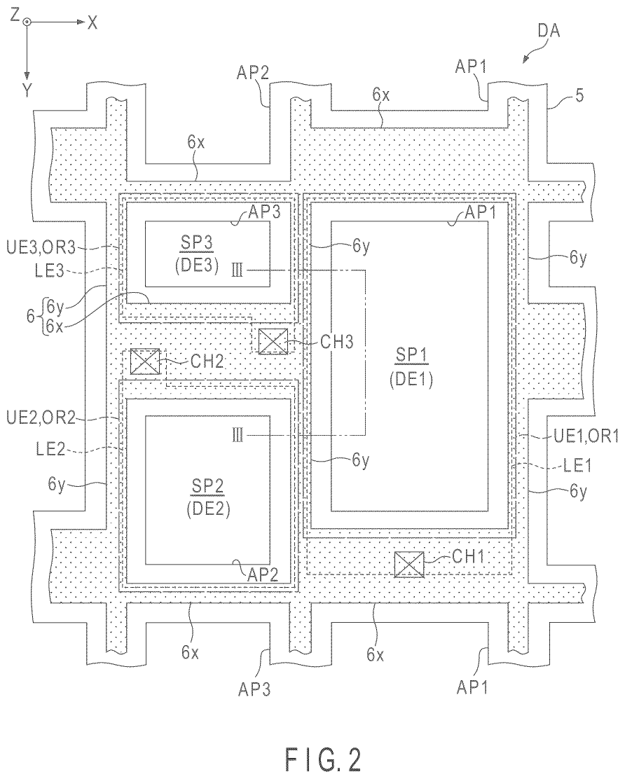

FIG. 2 is a schematic plan view showing an example of the layout of the sub-pixels SP1, SP2, and SP3. In the example in FIG. 2, each of the sub-pixels SP2 and SP3 is arranged with the sub-pixels SP1 in the first direction X. Further, the second sub-pixel SP2 and the third sub-pixel SP3 are arranged in the second direction Y.

When the sub-pixels SP1, SP2, and SP3 are arranged in such a layout, a row in which the sub-pixels SP2 and SP3 are alternately arranged in the second direction Y and a row in which a plurality of sub-pixels SP1 are repeatedly arranged in the second direction Y are formed in the display area DA. These rows are alternately arranged in the first direction X. Incidentally, the layout of the sub-pixels SP1, SP2, and SP3 is not limited to the example in FIG. 2.

A rib 5 and a partition 6 are arranged in the display area DA. The rib 5 includes pixel apertures AP1, AP2, and AP3 in the sub-pixels SP1, SP2, and SP3, respectively. In the example in FIG. 2, the pixel aperture AP1 is greater than the pixel aperture AP2, and the pixel aperture AP2 is greater than the pixel aperture AP3.

The partition 6 is arranged at a boundary of adjacent sub-pixels SP and overlaps with the rib 5 in plan view. The partition 6 comprises a plurality of first partitions 6x extending in the first direction X and a plurality of second partitions 6y extending in the second direction Y. The plurality of first partitions 6x are arranged between two pixel apertures AP1 adjacent to each other in the second direction Y and between the pixel apertures AP2 and AP3 adjacent to each other in the second direction Y. The second partitions 6y are arranged between the pixel apertures AP1 and AP2 adjacent to each other in the first direction X and between the pixel apertures AP1 and AP3 adjacent to each other in the first direction X.

In the example in FIG. 2, the first partitions 6x and the second partitions 6y are connected to each other. Thus, the partition 6 has a grating pattern surrounding the pixel apertures AP1, AP2, and AP3 as a whole. The partition 6 is considered to include apertures in the sub-pixels SP1, SP2, and SP3, similarly to the rib 5.

The sub-pixel SP1 comprises a lower electrode LE1, an upper electrode UE1, and an organic layer OR1 each overlapping with the pixel aperture AP1. The sub-pixel SP2 comprises a lower electrode LE2, an upper electrode UE2, and an organic layer OR2 each overlapping with the pixel aperture AP2. The sub-pixel SP3 comprises a lower electrode LE3, an upper electrode UE3, and an organic layer OR3 each overlapping with the pixel aperture AP3.

Portions of the lower electrode LE1, the upper electrode UE1, and the organic layer OR1 which overlap with the pixel aperture AP1 constitute the display element DE1 of the sub-pixel SP1. Portions of the lower electrode LE2, the upper electrode UE2, and the organic layer OR2 which overlap with the pixel aperture AP2 constitute the display element DE2 of the sub-pixel SP2. Portions of the lower electrode LE3, the upper electrode UE3, and the organic layer OR3 which overlap with the pixel aperture AP3 constitute the display element DE3 of the sub-pixel SP3. The display elements DE1, DE2, and DE3 may further include a cap layer to be described below. The rib 5 and the partition 6 surround each of these display elements DE1, DE2, and DE3.

The lower electrode LE1 is connected to the pixel circuit 1 (see FIG. 1) of the sub-pixel SP1 through a contact hole CH1. The lower electrode LE2 is connected to the pixel circuit 1 of the sub-pixel SP2 through a contact hole CH2. The lower electrode LE3 is connected to the pixel circuit 1 of the sub-pixel SP3 through a contact hole CH3. In the example in FIG. 2, the contact holes CH1, CH2, and CH3 overlap with the rib 5 and the partition 6 as a whole. However, the configuration is not limited to this example.

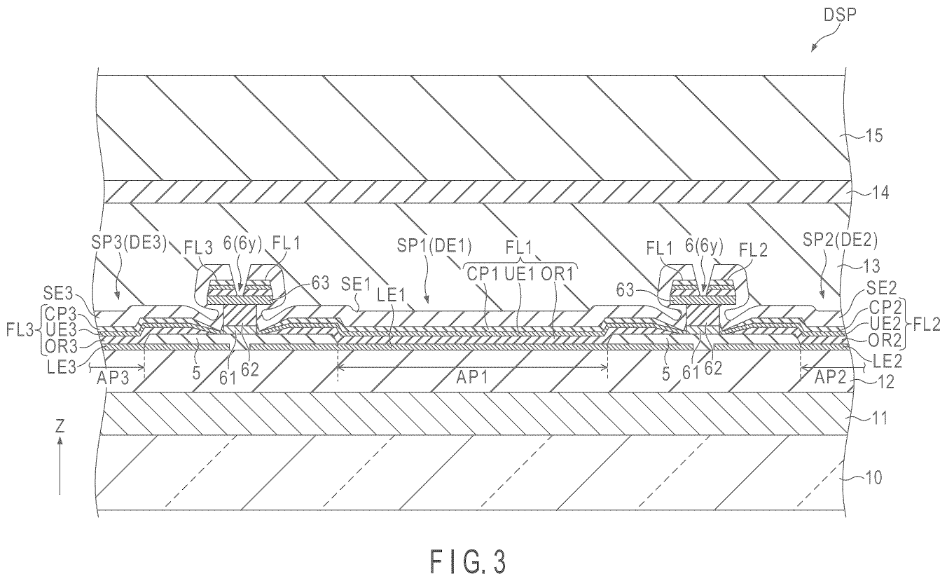

FIG. 3 is a schematic cross-sectional view of the display device DSP along the III-III line of FIG. 2. A circuit layer 11 is arranged on the substrate 10 described above. The circuit layer 11 includes various circuits and lines such as the pixel circuit 1, the scanning line GL, the signal line SL, and the power line PL shown in FIG. 1.

The circuit layer 11 is covered with an insulating layer 12. The insulating layer 12 functions as a planarization film for planarizing uneven parts generated by the circuit layer 11. Although not shown in the cross-section of FIG. 3, the above contact holes CH1, CH2, and CH3 are provided in the insulating layer 12.

The lower electrodes LE1, LE2, and LE3 are arranged on the insulating layer 12. The rib 5 is arranged on the insulating layer 12 and the lower electrodes LE1, LE2, and LE3. End parts of the lower electrodes LE1, LE2, and LE3 are covered with the rib 5.

The partition 6 comprises a bottom portion 61 arranged on the rib 5, a stem portion 62 arranged on the bottom portion 61, and a top portion 63 arranged on the stem portion 62. The top portion 63 has a width greater than those of the bottom portion 61 and the stem portion 62. Thus, in FIG. 3, the both end parts of the top portion 63 protrude relative to the side surfaces of the bottom portion 61 and the stem portion 62. This shape of the partition 6 is referred to as an overhang shape.

The organic layer OR1 covers the lower electrode LE1 through the pixel aperture AP1. The upper electrode UE1 covers the organic layer OR1 and is opposed to the lower electrode LE1. The organic layer OR2 covers the lower electrode LE2 through the pixel aperture AP2. The upper electrode UE2 covers the organic layer OR2 and is opposed to the lower electrode LE2. The organic layer OR3 covers the lower electrode LE3 through the pixel aperture AP3. The upper electrode UE3 covers the organic layer OR3 and is opposed to the lower electrode LE3.

In the example in FIG. 3, a cap layer CP1 is arranged on the upper electrode UE1, a cap layer CP2 is arranged on the upper electrode UE2, and a cap layer CP3 is arranged on the upper electrode UE3. The cap layers CP1, CP2, and CP3 have a role as optical adjustment layers for improving the outcoupling efficiency of the light emitted from the organic layers OR1, OR2, and OR3, respectively.

In the following descriptions, a stacked layer body including the organic layer OR1, the upper electrode UE1, and the cap layer CP1 is referred to as a thin film FL1, a stacked layer body including the organic layer OR2, the upper electrode UE2, and the cap layer CP2 is referred to as a thin film FL2, and a stacked layer body including the organic layer OR3, the upper electrode UE3, and the cap layer CP3 is referred to as a thin film FL3.

A part of the thin film FL1 is located on the top portion 63. This part is separated from a portion of the thin film FL1, which is located below the partition 6 (in other words, a portion constituting the display element DE1). Similarly, a part of the thin film FL2 is located on the top portion 63, and this part is separated from a portion of the thin film FL2, which is located below the partition 6 (in other words, a portion constituting the display element DE2). Further, a part of the thin film FL3 is located on the top portion 63, and this part is separated from a part of the thin film FL3, which is located below the partition 6 (in other words, a portion constituting the display element DE3).

Sealing layers SE1, SE2, and SE3 are arranged in the sub-pixels SP1, SP2 and SP3, respectively. The sealing layer SE1 continuously covers the thin film FL1 and the partition 6 around the sub-pixel SP1. The sealing layer SE2 continuously covers the thin film FL2 and the partition 6 around the sub-pixel SP2. The sealing layer SE3 continuously covers the thin film FL3 and the partition 6 around the sub-pixel SP3.

In the example in FIG. 3, the thin film FL1 and the sealing layer SE1 located on the partition 6 between the sub-pixels SP1 and SP2 are separated from the thin film FL2 and the sealing layer SE2 located on this partition 6. In addition, the thin film FL1 and the sealing layer SE1 located on the partition 6 between the sub-pixels SP1 and SP3 are separated from the thin film FL3 and the sealing layer SE3 located on this partition 6.

The sealing layers SE1, SE2, and SE3 are covered with a resin layer 13. The resin layer 13 is covered with a sealing layer 14. The sealing layer 14 is covered with a resin layer 15. The resin layers 13 and 15 and the sealing layer 14 are provided continuously on a whole body of at least the display area DA, and partially extend to the surrounding area SA.

A cover member such as a polarizer, a touch panel, a protective film, or a cover glass may be provided further above the resin layer 15. This cover member may be attached to the resin layer 15 via, for example, an adhesive layer such as an optical clear adhesive (OCA).

The insulating layer 12 is formed of an organic insulating material. Each of the rib 5 and the sealing layers 14, SE1, SE2, and SE3 can be formed of an inorganic insulating material such as silicon nitride (SiN), silicon oxide (SiO), silicon oxynitride (SiON), or aluminum oxide (Al₂O₃). Each of the rib 5 and the sealing layers 14, SE1, SE2, and SE3 may have a single-layer structure formed of any of the inorganic insulating materials, or may have a stacked structure in which the layers of two or more types of inorganic insulating materials are stacked. The inorganic insulating materials forming the rib 5 and the sealing layers 14, SE1, SE2, and SE3, respectively, may be the same as each other or different from each other.

The resin layers 13 and 15 are formed of, for example, a resin material (organic insulating material) such as epoxy resin or acrylic resin. The lower electrodes LE1, LE2, and LE3 include, for example, a reflective layer formed of silver (Ag) and a pair of conductive oxide layers that cover upper and lower surfaces of the reflective layer, respectively. Each of the conductive oxide layers can be formed of, for example, a transparent conductive oxide such as indium tin oxide (ITO), indium zinc oxide (IZO), or indium gallium zinc oxide (IGZO).

The upper electrodes UE1, UE2, and UE3 are formed of, for example, a metallic material such as an alloy (MgAg) of magnesium and silver. For example, the lower electrodes LE1, LE2, and LE3 correspond to anodes, and the upper electrodes UE1, UE2, and UE3 correspond to cathodes.

Each of the organic layers OR1, OR2, and OR3 includes a stacked structure of, for example, a hole-injection layer, a hole-transport layer, an electron blocking layer, a light emitting layer, a hole blocking layer, an electron-transport layer, and an electron-injection layer. The organic layers OR1, OR2, and OR3 may have a so-called tandem structure including a plurality of light emitting layers.

The cap layers CP1, CP2, and CP3 are formed of, for example, a multilayer body of a plurality of transparent thin films. The multilayer body may include a thin film formed of an inorganic material and a thin film formed of an organic material, as the plurality of thin films. In addition, these thin films have refractive indices different from each other. The materials of the thin films constituting the multilayer body are different from the materials of the upper electrodes UE1, UE2, and UE3 and also different from the materials of the sealing layers SE1, SE2, and SE3. The cap layers CP1, CP2, and CP3 may be omitted.

The bottom portion 61 can be formed of, for example, a conductive material such as aluminum (Al), titanium (Ti), titanium nitride (TiN), molybdenum (Mo), tungsten (W), a molybdenum-tungsten alloy (MoW), a molybdenum-niobium alloy (MoNb), ITO or IZO. The bottom portion 61 may have a single-layer structure formed of any of these materials or may have a stacked structure including layers formed of different materials.

The stem portion 62 can be formed of an insulating material such as silicon nitride, silicon oxide, or silicon oxynitride. The stem portion 62 may have a single-layer structure formed of any of these materials or may have a stacked structure including layers formed of different materials.

The top portion 63 may be formed of, for example, an insulating material such as silicon nitride, silicon oxide, and silicon oxynitride or may be formed of a conductive material such as aluminum, titanium, titanium nitride, molybdenum, tungsten, a molybdenum-tungsten alloy, a molybdenum-niobium alloy (MoNb), ITO or IZO. The top portion 63 may have a single-layer structure formed of any of these materials, or may have a stacked structure including layers formed of different materials. When the top portion 63 has a stacked structure, the top portion 63 may include a conductive layer formed of a conductive material and an insulating layer formed of an insulating material. In this case, the insulating layer may be arranged on the conductive layer, or conversely, the conductive layer may be arranged on the insulating layer.

The upper electrodes UE1, UE2, and UE3 are in contact with the side surfaces of the bottom portion 61. A common voltage is supplied to the bottom portion 61. This common voltage is supplied to each of the upper electrodes UE1, UE2, and UE3. A pixel voltage is supplied to the lower electrodes LE1, LE2, and LE3 through the pixel circuits 1 included in the respective sub-pixels SP1, SP2, and SP3.

The organic layers OR1, OR2, and OR3 emit light in response to application of a voltage. More specifically, when a potential difference is formed between the lower electrode LE1 and the upper electrode UE1, the light emitting layer of the organic layer OR1 emits light of the blue wavelength range. When a potential difference is formed between the lower electrode LE2 and the upper electrode UE2, the light emitting layer of the organic layer OR2 emits light of the green wavelength range. When a potential difference is formed between the lower electrode LE3 and the upper electrode UE3, the light emitting layer of the first organic layer OR3 emits light of the red wavelength range.

As another example, the light emitting layers of the organic layers OR1, OR2, and OR3 may emit light of the same color (for example, white). In this case, the display device DSP may comprise a color filter that converts the light emitted from the light emitting layers into light of the color corresponding to the sub-pixels SP1, SP2, and SP3. In addition, the display device DSP may comprise a layer including quantum dots that are excited by the light emitted from the light emitting layers to generate the light of the colors corresponding to the sub-pixels SP1, SP2, and SP3.

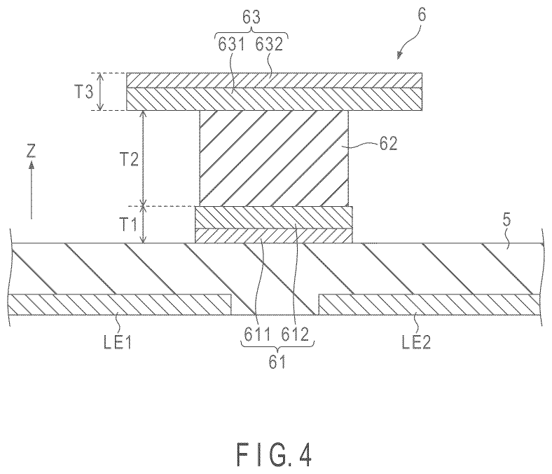

FIG. 4 is a schematic cross-sectional view showing an example of a configuration which can be applied to the partition 6. In this example, the bottom portion 61 includes a first bottom layer 611 and a second bottom layer 612 arranged on the first bottom layer 611. In addition, the top portion 63 includes a first top layer 631, and a second top layer 632 arranged on the first top layer 631. The stem portion 62 has a single-layer structure.

Materials of the first bottom layer 611 and the second bottom layer 612 can be appropriately selected from the conductive materials described above as the materials of the bottom portion 61. Materials of the first top layer 631 and the second top layer 632 can be appropriately selected from the insulating materials and the conductive materials described above as the materials of the top portion 63.

Incidentally, “the first” and “the second” added to the bottom layers 611 and 622 are simply for the sake of distinguishing these bottom layers 611 and 622 from each other. In other words, the positional relationship between “the first bottom layer” and “the second bottom layer” does not necessarily indicate “the first bottom layer” located on a lower side and “the second bottom layer” located on an upper side as shown in the example in FIG. 4. As another example, among multiple layers constituting the bottom portion 61, the layer located on the upper side may be referred to as “the first bottom layer” and the layer located below “the first bottom layer” may be referred to as the “the second bottom layer”.

Similarly, “the first” and “the second” are added to the top layers 631 and 632 simply for the sake of distinguishing these top layers 631 and 632 from each other. In other words, the positional relationship between “the first top layer” and “the second top layer” does not necessarily indicate “the first top layer” located on a lower side and “the second top layer” located on an upper side as shown in the example in FIG. 4. As another example, among multiple layers constituting the top portion 63, the layer located on an upper side may be referred to as “the first top layer” and the layer located below “the first top layer” may be referred to as “the second top layer”.

As shown in FIG. 4, both end parts of the first top layer 631 and the second top layer 632 protrude in the width direction of the partition 6 further than the side surfaces of each of the first bottom layer 611, the second bottom layer 612, and the stem portion 62. In the example in FIG. 4, the widths of the first bottom layer 611 and the second bottom layer 612 are slightly greater than the width of the stem portion 62. As another example, the widths of the first bottom layer 611 and the second bottom layer 612 may be equivalent to the width of the stem portion 62.

The bottom portion 61 has thickness T1, the stem portion 62 has thickness T2, and the top portion 63 has thickness T3. In the example in FIG. 4, the thickness T2 is greater than the thickness T1 (T1<T2), and the thickness T3 is greater than the thickness T2 (T2>T3). The thicknesses T1 and T3 are, for example, equivalent to each other. However, the relationship among the thicknesses T1, T2, and T3 is not limited to this example.

The configuration of the partition 6 shown in FIG. 4 is merely an example. The bottom portion 61 and the top portion 63 may have a single-layer structure or may have a stacked structure of three or more layers. In addition, the stem portion 62 may have a stacked structure of two or more layers.

Next, a method of manufacturing the display device DSP in an example in which the partition 6 has the configuration shown in FIG. 4 will be described.

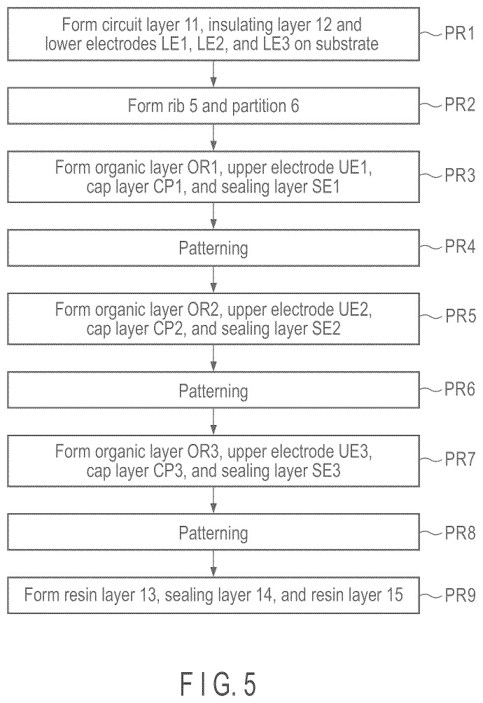

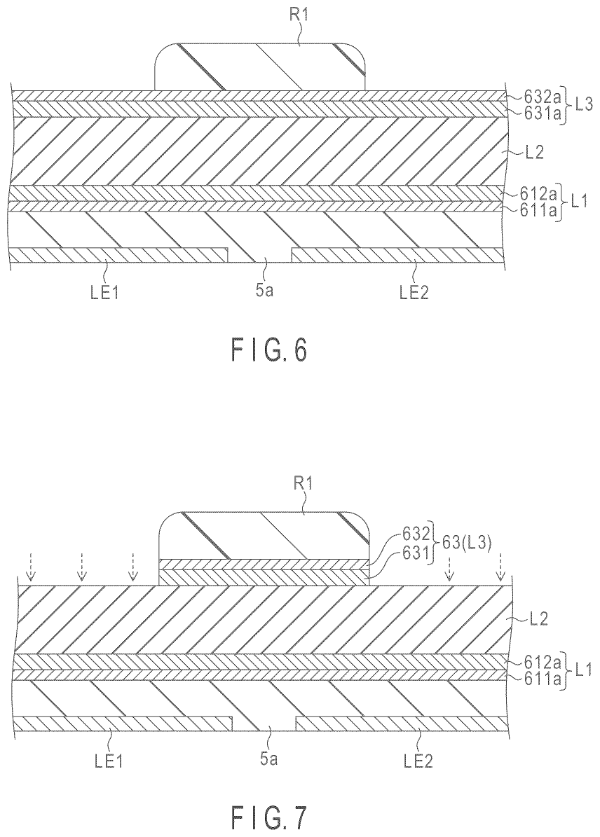

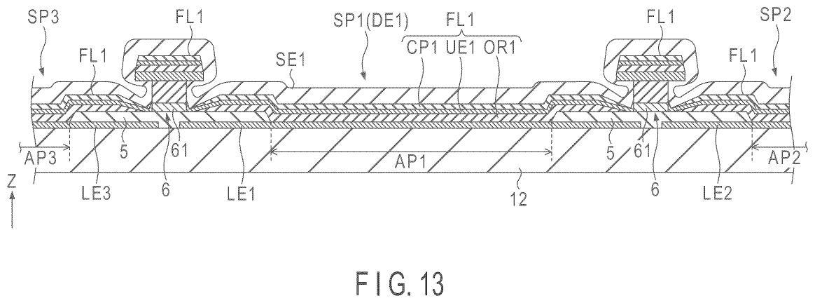

FIG. 5 is a flowchart showing an example of the method of manufacturing the display device DSP. FIG. 6 to FIG. 18 each are schematic cross-sectional views showing a process in the method of manufacturing the display device DSP. In FIGS. 6 to 12, the substrate 10, the circuit layer 11, and the insulating layer 12 are omitted. In addition, in FIG. 13 to FIG. 18, the substrate 10 and the circuit layer 11 are omitted.

In manufacturing the display device DSP, the circuit layer 11, the insulating layer 12, and the lower electrodes LE1, LE2, and LE3 are first formed on the substrate 10 (process PR1). Further, the rib 5 and the partition 6 are formed (process PR2).

In the process PR2, as shown in FIG. 6, an insulating layer 5a serving as a base of the rib 5 is formed, a first layer L1 serving as a base of the bottom portion 61 is formed on the insulating layer 5a, a second layer L2 serving as a base of the stem portion 62 is formed on the first layer L1, and a third layer L3 serving as a base of the top portion 63 is formed on the second layer L2. Further, a resist R1 patterned into the plan shape of the partition 6 is formed on the third layer L3.

The first layer L1 includes a first bottom layer 611a, and a second bottom layer 612a which covers the first bottom layer 611a. In addition, the third layer L3 includes a first top layer 631a, and a second top layer 632a which covers the first top layer 631a.

Next, the third layer L3 is patterned by a first etching process shown in FIG. 7. The first etching process includes etching to remove a portion of the second top layer 632a exposed from the resist R1 and etching to remove a portion of the first top layer 631a exposed from the resist R1. By these etching processes, the top portion 63 including the first top layer 631 and the second top layer 632 is formed.

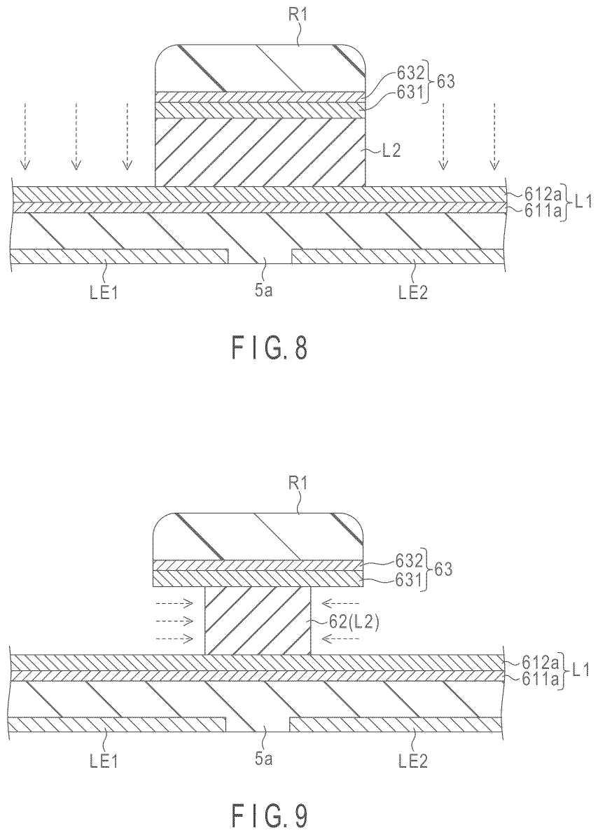

After the formation of the top portion 63, the second layer L2 is patterned by a second etching process. As shown in FIG. 8, in the second etching process, a portion of the second layer L2 exposed from the resist R1 is first removed by anisotropic etching. Further, as shown in FIG. 9, the width of the second layer L2 is made smaller by isotropic etching. Thus, the stem portion 62 having the width smaller than the width of the top portion 63 is formed.

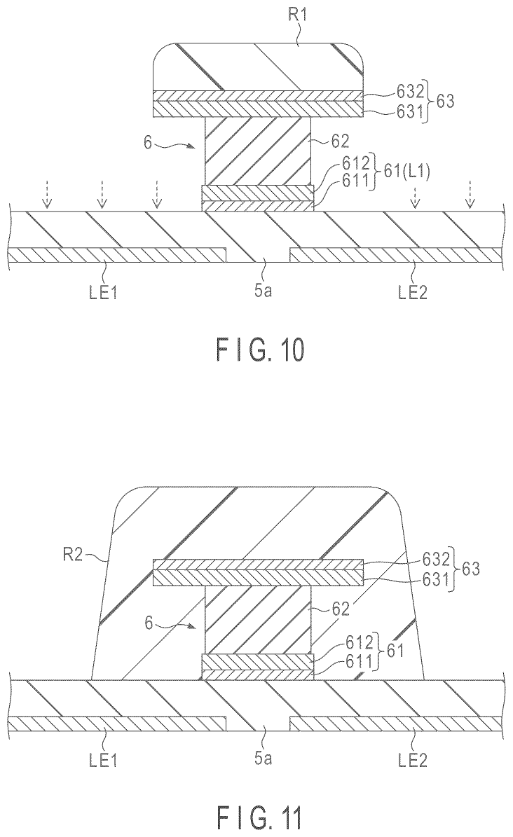

After the formation of the stem portion 62, the first layer L1 is patterned by a third etching process shown in FIG. 10. The third etching process includes etching to remove a portion of the second bottom layer 612a exposed from the stem portion 62, and etching to remove a portion of the first bottom layer 611a exposed from the stem portion 62. By these etching processes, the bottom portion 61 including the first bottom layer 611 and the second bottom layer 612 is formed.

Thus, the partition 6 is formed by patterning the first layer L1, the second layer L2, and the third layer L3 by the first to third etching processes. After the formation of the partition 6, the resist R1 is removed.

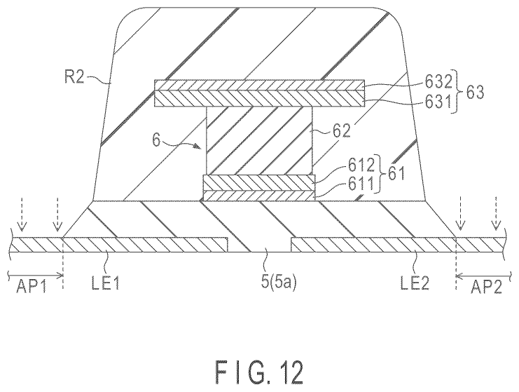

Subsequently, as shown in FIG. 11, a resist R2 patterned into the plan shape of the rib 5 is arranged. Further, as shown in FIG. 12, a portion of the insulating layer 5a exposed from the resist R2 is removed by etching. Thus, the rib 5 including the pixel apertures AP1, AP2, and AP3 is formed. After this etching, the resist R2 is removed.

In the example in FIG. 6 to FIG. 12, a case where the pixel apertures AP1, AP2, and AP3 of the rib 5 are formed after the formation of the partition 6 is shown. As another example, the partition 6 may be formed after the formation of the pixel apertures AP1, AP2, and AP3.

After the formation of the rib 5 and the partition 6, a process for forming the display elements DE1, DE2, and DE3 is performed. In the present embodiment, it is assumed that the display element DE1 is formed first, the display element DE2 is formed next, and the display element DE3 is formed last. However, the order of formation of the display elements DE1, DE2, and DE3 is not limited to this example.

In the formation of the display element DE1, first, as shown in FIG. 13, the organic layer OR1 which covers the lower electrode LE1 through the pixel aperture AP1, the upper electrode UE1 which covers the organic layer OR1 and is in contact with the side surfaces of the bottom portion 61, and the cap layer CP1 which covers the upper electrode UE1 are formed in order by vapor deposition, and further, the sealing layer SE1 which continuously covers the cap layer CP1 and the partition 6 is formed by chemical vapor deposition (CVD) (process PR3).

The thin film FL1 including the organic layer OR1, the upper electrode UE1, and the cap layer CP1 is formed in a whole body of at least the display area DA and is arranged not only in the sub-pixel SP1 but also in the sub-pixels SP2 and SP3 and on the partition 6. The thin film FL1 is divided by the partition 6 having an overhang shape. The sealing layer SE1 is formed in a whole body of the display area DA and continuously covers the thin film FL1 and the partition 6 without being divided by the partition 6.

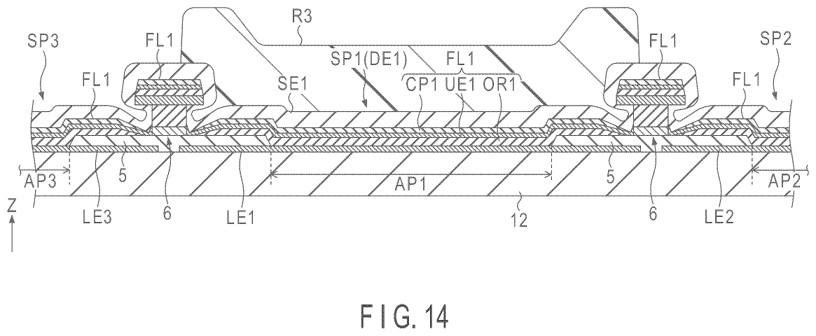

After the process PR3, the thin film FL1 and the sealing layer SE1 are patterned (process PR4). In this patterning, as shown in FIG. 14, a resist R3 is arranged on the sealing layer SE1. The resist R3 covers the sub-pixel SP1 and a part of the partition 6 in the surrounding of the sub-pixel SP1.

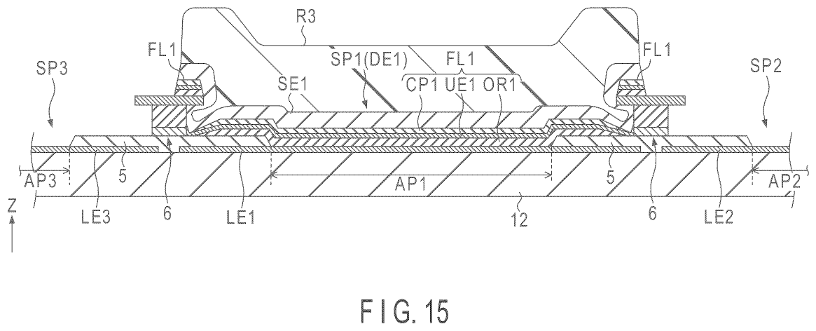

As a result, portions of the thin film FL1 and the sealing layer SE1 exposed from the resist R3 is removed, as shown in FIG. 15, by etching using the resist R3 as a mask. For example, this etching includes wet etching and dry etching which are performed in order for the sealing layer SE1, the cap layer CP1, the upper electrode UE1, and the organic layer OR1.

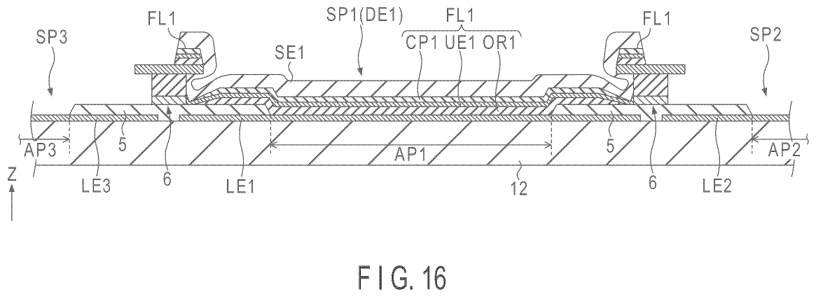

After the process shown in FIG. 15, the resist R3 is removed. In this manner, as shown in FIG. 16, a substrate in which the display element DE1 and the sealing layer SE1 are formed in the sub-pixel SP1, and no display elements or sealing layers are formed in the sub-pixel SP2 and the sub-pixel SP3 can be obtained.

The display element DE2 is formed by a procedure similar to the procedure of the display element DE1. In other words, after the process PR4, the organic layer OR2 which covers the lower electrode LE2 through the pixel aperture AP2, the upper electrode UE2 which covers the organic layer OR2 and the cap layer CP2 which covers the upper electrode UE2 are formed in order by vapor deposition, and further, the sealing layer SE2 which continuously covers the cap layer CP2 and the partition 6 is formed by CVD (process PR5).

The thin film FL2 including the organic layer OR2, the upper electrode UE2, and the cap layer CP2 is formed in a whole body of at least the display area DA and is arranged not only in the sub-pixel SP2 but also in the sub-pixels SP1 and SP3 and on the partition 6. The thin film FL2 is divided by the partition 6 having an overhang shape. The sealing layer SE2 is formed in a whole body of the display area DA and continuously covers the thin film FL2 and the partition 6 without being divided by the partition 6.

After the process PR5, the thin film FL2 and the sealing layer SE2 are patterned by wet etching and dry etching (process PR6). The flow of this patterning is similar to that of the process PR4.

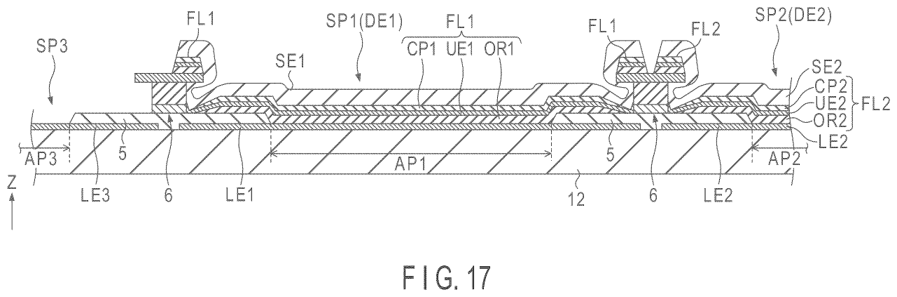

After the processes PR6, a substrate in which the display element DE1 and the sealing layer SE1 are formed in the sub-pixel SP1, the display element DE2 and the sealing layer SE2 are formed in the sub-pixel SP2, and no display elements or sealing layers are formed in the sub-pixel SP3 can be obtained as shown in FIG. 17.

The display element DE3 is formed by a procedure similar to the procedures of the display elements DE1 and DE2. In other words, after the process PR6, the organic layer OR3 which covers the lower electrode LE3 through the pixel aperture AP3, the upper electrode UE3 which covers the organic layer OR3, and the cap layer CP3 which covers the upper electrode UE3 are formed in order by vapor deposition, and further, the sealing layer SE3 which continuously covers the cap layer CP3 and the partition 6 is formed by CVD (process PR7).

The thin film FL3 including the organic layer OR3, the upper electrode UE3 and the cap layer CP3 is formed in a whole body of at least the display area DA, and is arranged not only in the sub-pixel SP3 but also in the sub-pixels SP1 and SP2 and on the partition 6. The thin film FL3 is divided by the partition 6 having an overhang shape. The sealing layer SE3 is formed in a whole body of at least the display area DA and continuously covers the thin film FL3 and the partition 6 without being divided by the partition 6.

After the process PR7, the thin film FL3 and the sealing layer SE3 are patterned by wet etching and dry etching (process PR8). The flow of this patterning is similar to that of the process PR4.

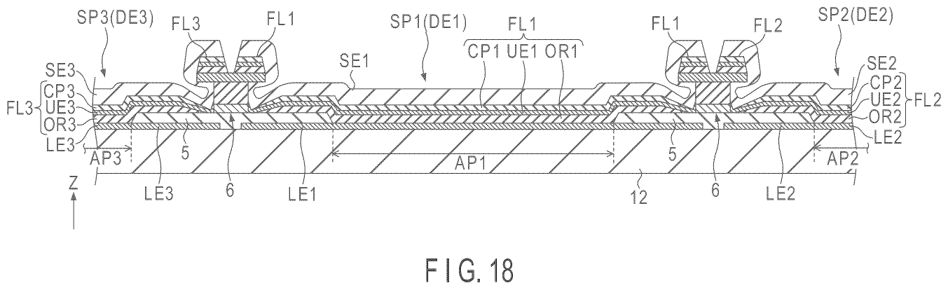

After the process PR8, a substrate in which the display element DE1 and the sealing layer SE1 are formed in the sub-pixel SP1, the display element DE2 and the sealing layer SE2 are formed in the sub-pixel SP2, and the display element DE3 and the sealing layer SE3 are formed in the sub-pixel SP3 can be obtained as shown in FIG. 18.

After the display elements DE1, DE2, and DE3 and the sealing layers SE1, SE2, and SE3 are formed, the resin layer 13, the sealing the layer 14, and the resin layer 15 shown in FIG. 3 are formed in order (process PR9). The display device DSP is thereby completed.

In the method of manufacturing the display device DSP of the present embodiment described above, the thin films FL1, FL2, and FL3 formed by vapor deposition are divided by the partition 6 having an overhang shape. Further, by covering these divided thin films FL1, FL2, and FL3 with the sealing layers SE1, SE2, and SE3, respectively, the individually sealed display elements DE1, DE2, and DE3 can be obtained. The partition 6 also functions as a line which supplies electricity to the upper electrodes UE1, UE2, and UE3.

In order to satisfactorily divide the thin films FL1, FL2, and FL3, the thicknesses of the bottom portion 61 and the stem portion 62 of the partition 6, and the protrusion length of the top portion 63 from the stem portion 62 need to be sufficiently great. If the entire bottom portion 61 and stem portion 62 are formed by conductive materials and are made thicker, the resistance of the partition 6 are greatly reduced.

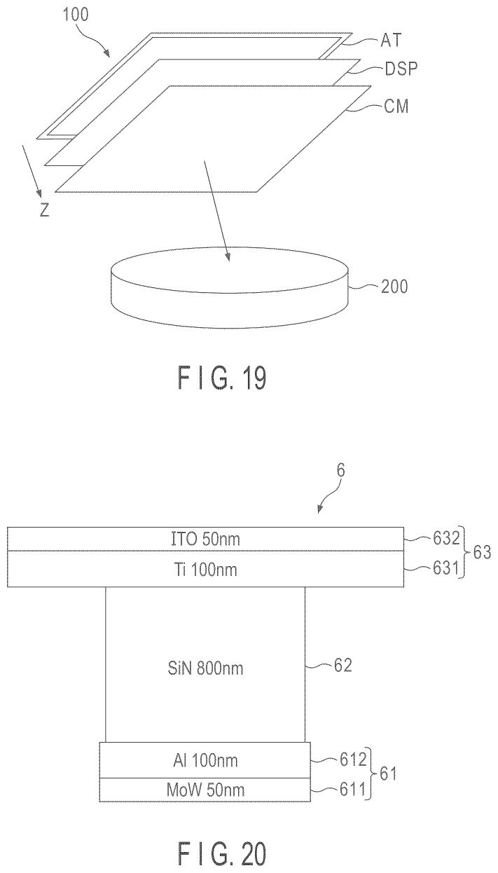

Depending on the aspect of use of the display device DSP, a significant decrease in the resistance of the partition 6 is not desirable. FIG. 19 is a schematic diagram showing this example. In this diagram, the display device DSP is mounted on an electronic apparatus 100. The electronic apparatus 100 is, for example, a mobile terminal such as a smartphone or a wearable terminal such as a smartwatch.

The electronic apparatus 100 comprises a cover member CM arranged on a display surface side of the display device DSP (upper surface side of the resin layer 15 shown in FIG. 3) and an antenna AT arranged on a back surface side of the display device DSP (bottom side of the substrate 10 shown in FIG. 3). The cover member CM is formed of, for example, glass. The antenna AT receives and transmits radio waves for near field wireless communication (NFC).

When the electronic apparatus 100 having this configuration is used for the near field wireless communication with a reader 200, the electronic apparatus 100 is held over the reader 200, for example, in a posture in which the cover member CM is opposed to the reader 200. At this time, the display device DSP is interposed between the antenna AT and the reader 200. In this case, if the resistance of the partition 6 is excessively low, the partition 6 may affect the sensitivity of the communication between the antenna AT and the reader 200.

In contrast, the partition 6 of the present embodiment comprises the conductive bottom portion 61 and the insulating stem portion 62. In this configuration, the resistance of the partition 6 can be increased compared to a case where the entire partition 6 or the entire portion of the partition 6 excluding the top portion 63 is formed of a conductive material. As a result, in a case where the display device DSP is used in the example shown in FIG. 19, it is possible to satisfactorily maintain sensitivity for the near-field wireless communication.

The resistance of the partition 6 can be adjusted to an appropriate value by adjusting the thickness T1 of the bottom portion 61 shown in FIG. 4. In other words, in order to increase the resistance of the partition 6, the thickness T1 may be made smaller. In addition, in order to decrease the resistance, the thickness T1 may be made greater. By adjusting the thickness T1, it is possible to achieve the desired resistance of the partition 6 according to the performance required for the display device DSP. In addition, the height of the partition 6 can be controlled independently of the resistance when the height of the partition 6 is adjusted mainly by the thickness T2 of the stem portion 62.

In the manufacturing method disclosed in the present embodiment, the following conditions should preferably be satisfied to form a well-shaped partition 6.

### [Condition 1]

In a case where the first layer L1 includes a layer formed of the conductive first material, the second layer L2 includes a layer formed of the insulating second material, and the third layer L3 includes a layer formed of the third material, the etching rate of the third material in the second etching process shown in FIG. 9 is lower than the etching rate of the second material in this second etching process.

### [Condition 2]

In a case where the first layer L1 includes the layer formed of the conductive first material, the second layer includes the layer formed of the insulating second material, and the third layer includes the layer formed of the third material, the etching rate of the third material in the third etching process shown in FIG. 10 is lower than the etching rate of the first material in this third etching process.

### [Condition 3]

In a case where the first layer L1 includes the layer formed of the conductive first material, the second layer L2 includes the layer formed of the insulating second material, and the third layer L3 includes the layer formed of the first material, the layer formed of the first material included in the third layer L3 is formed thicker than the layer formed of the first material included in the first layer L1.

By satisfying the condition 1, erosion of the top portion 63 in the second etching process is suppressed and the width of the top portion 63 can be satisfactorily maintained. Similarly, by satisfying the condition 2, erosion of the top portion 63 in the third etching process is suppressed and the width of the top portion 63 can be satisfactorily maintained. Thus, the overhang shape of the partition 6 is stabilized.

In addition, when the first layer L1 and the third layer L3 include the same layer of the first material as in the case of the condition 3, the third layer L3 may be eroded in the third etching process targeting the first layer L1. However, when the layer of the first material included in the third layer L3 is formed to be thicker, this loss of the layer is suppressed. Therefore, as in the case of conditions 1 and 2, the overhang shape of the partition 6 is stabilized.

Next, some examples of the partition 6 will be described. In these examples, it is assumed that the bottom portion 61 includes the first bottom layer 611 and the second bottom layer 612, the top portion 63 includes the first top layer 631 and the second top layer 632, and the stem portion 62 includes a single layer structure as shown in FIG. 4. The configuration of the partition 6 is not limited to these examples, and various configurations that satisfy, for example, at least one of the conditions 1 to 3 can be applied.

### Example 1

FIG. 20 is a diagram showing the partition 6 according to the example 1. In the example 1, a first bottom layer 611 is formed by a molybdenum-tungsten alloy, a second bottom layer 612 is formed by aluminum, a stem portion 62 is formed by silicon nitride, a first top layer 631 is formed by titanium, and a second top layer 632 is formed by ITO.

For example, the thickness of the first bottom layer 611 is 50 nm, the thickness of the second bottom layer 612 is 100 nm, which is thicker than the first bottom layer 611, the thickness of the stem portion 62 is 800 nm, the thickness of the first top layer 631 is 100 nm, and the thickness of the second top layer 632 is 50 nm, which is thinner than the first top layer 631.

Incidentally, sputtering can be used for the formation of the molybdenum-tungsten alloy, aluminum, titanium, and ITO. In addition, CVD can be used for the formation of silicon nitride.

The second top layer 632 formed of ITO is, for example, patterned by wet etching using an etchant containing oxalic acid. The first top layer 631 formed of titanium, the stem portion 62 formed of silicon nitride, and the first bottom layer 611 formed of the molybdenum-tungsten alloy are patterned by dry etching using, for example, fluorine-based etching gas. The second bottom layer 612 formed of aluminum is patterned by wet etching using, for example, an etchant containing phosphoric acid, nitric acid, and acetic acid.

In the example 1, each of the molybdenum-tungsten alloy forming the first bottom layer 611 and aluminum forming the second bottom layer 612 is an example of the first material, silicon nitride forming the stem portion 62 is an example of the second material, and titanium forming the first top layer 631 is an example of the third material.

In other words, the etching rate of titanium (third material) in dry etching (second etching process) to process the stem portion 62 formed of silicon nitride (second material) is lower than the etching rate of silicon nitride (second material) in this etching. Therefore, the example 1 satisfies the condition 1.

In addition, the etching rate of titanium (third material) in dry etching (third etching process) to process the first bottom layer 611 formed of the molybdenum-tungsten alloy (first material) is lower than the etching rate of the molybdenum tungsten alloy (first material) in this dry etching. Similarly, the etching rate of titanium (third material) in wet etching (third etching process) to process the second bottom layer 612 formed of aluminum (first material) is lower than the etching rate of aluminum (first material) in this etching. Thus, the example 1 satisfies the condition 2.

### Example 2

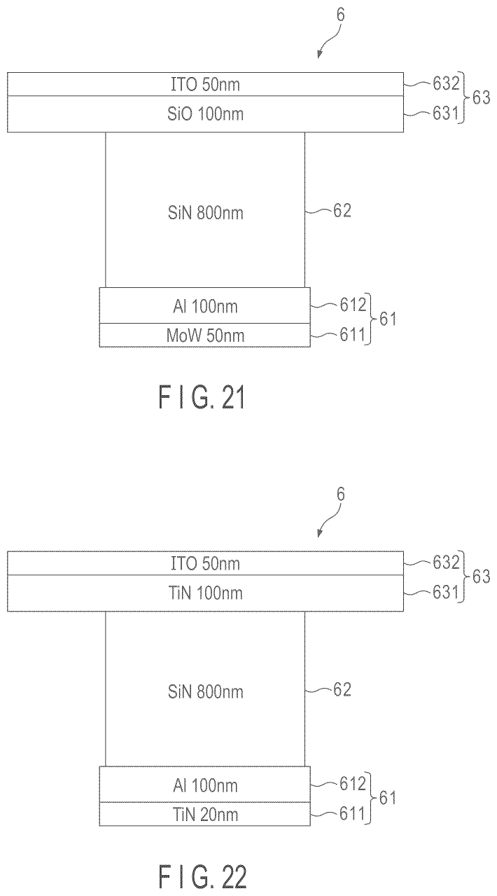

FIG. 21 is a diagram showing the partition 6 according to the example 2. In the example 2, a first top layer 631 is formed of silicon oxide. The structures other than the first top layer 631 are the same as those in the example 1.

The thickness of the first top layer 631 is, for example, 100 nm. CVD can be used for the formation of silicon oxide. In addition, the first top layer 631 formed of silicon oxide is patterned by dry etching using, for example, fluorine-based etching gas.

In the example 2, each of the molybdenum-tungsten alloy forming the first bottom layer 611 and aluminum forming the second bottom layer 612 is an example of the first material, silicon nitride forming the stem portion 62 is an example of the second material, and silicon oxide forming the first top layer 631 is an example of the third material.

In other words, the etching rate of silicon oxide (third material) in dry etching (second etching process) to process the stem portion 62 formed of silicon nitride (second material) is lower than the etching rate of silicon nitride (second material) in this etching. Thus, the example 2 satisfies the condition 1.

In addition, the etching rate of silicon oxide (third material) in dry etching (third etching process) to process the first bottom layer 611 formed of the molybdenum-tungsten alloy (first material) is lower than the etching rate of the molybdenum tungsten alloy (first material) in this dry etching. Similarly, the etching rate of silicon oxide (third material) in wet etching (third etching process) to process the second bottom layer 612 formed of aluminum (first material) is lower than the etching rate of aluminum (first material) in this etching. Thus, the example 2 satisfies the condition 2.

### Example 3

FIG. 22 is a diagram showing a partition 6 according to the example 3. In the example 3, a first bottom layer 611 and a first top layer 631 are formed by titanium nitride. The structures other than the first bottom layer 611 and the first top layer 631 are the same as those in the example 1.

For example, the thickness of the first bottom layer 611 is 20 nm and the thickness of the first top layer 631 is 100 nm. Sputtering can be used for forming titanium nitride. In addition, the first bottom layer 611 and the first top layer 631 formed of titanium nitride are patterned by dry etching using, for example, fluorine-based etching gas.

In the example 3, aluminum forming the second bottom layer 612 is an example of the first material, silicon nitride forming the stem portion 62 is an example of the second material, and titanium nitride forming the first top layer 631 is an example of the third material.

In this case, the etching rate of titanium nitride (third material) in dry etching (second etching process) to process the stem portion 62 formed of silicon nitride (second material) is lower than the etching rate of silicon nitride (second material) in this etching. Thus, the example 3 satisfies the condition 1.

In addition, the etching rate of titanium nitride (third material) in wet etching (third etching process) to process the second bottom layer 612 formed of aluminum (first material) is lower than the etching rate of aluminum (first material) in this etching. Therefore, the example 3 satisfies the condition 2.

Further, in the example 3, titanium nitride forming the first bottom layer 611 and the first top layer 631 can be regarded as the first material. In this case, since the thickness of the first bottom layer 611 is 20 nm and the thickness of the first top layer 631 is 100 nm, the example 3 satisfies the condition 3.

In the example 2 shown in FIG. 21, the first top layer 631 formed of silicon oxide is insulating and the second top layer 632 formed of ITO is conductive. In other words, the top portion 63 includes a stacked structure of a conductive layer and an insulating layer.

Various other forms of such a stacked structure can be assumed in addition to the example 2. For example, a conductive layer of the top portion 63 may be formed by any of aluminum, titanium, titanium nitride, molybdenum, a molybdenum-tungsten alloy, tungsten, and IZO. In addition, the insulating layer of the top portion 63 may be formed of any of silicon nitride and silicon oxynitride.

If the top portion 63 is formed only of an insulating material, the etching rate of the top portion 63 may be close to the etching rate of the stem portion 62, which is also formed of an insulating material, in the etching of the stem portion 62. In this case, the top portion 63 may also be eroded during the etching of the stem portion 62, and the overhang shape may not be maintained.

In contrast, in a case where the top portion 63 has a stacked structure of a conductive layer and an insulating layer, and when a material with an etching rate slower than the etching rate of the stem portion 62 is used for this conductive layer, the overhang shape can be desirably maintained by the conductive layer even if the insulating layer is eroded during the etching of the stem portion 62.

In addition, if the top portion 63 is formed only of a conductive material, the etching rate of the top portion 63 may be close to the etching rate of the bottom portion 61, which is also formed of a conductive material, in the etching of the bottom portion 61. Also in this case, the top portion 63 may be eroded during the etching of the bottom portion 61, and the overhang shape may not be maintained.

In contrast, when the top portion 63 has a stacked structure of a conductive layer and an insulating layer, and a material with an etching rate slower than the etching rate of the bottom portion 61 is used for this insulating layer, the overhang shape can be desirably maintained by the insulating layer even if the conductive layer is eroded during the etching of the bottom portion 61.

All of the display devices that can be implemented by a person of ordinary skill in the art through arbitrary design changes to the display device described above as the embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device manufacturing method, comprising:
forming a lower electrode;
forming a rib covering at least a part of the lower electrode; and
forming a partition on the rib, the partition including a conductive bottom portion, an insulating stem portion located on the bottom portion, and a top portion located on the stem portion and protruding relative to side surfaces of the stem portion, wherein
the formation of the partition includes:
forming a first layer including a layer formed of a conductive first material;
forming a second layer including a layer formed of an insulating second material on the first layer;
forming a third layer including a layer formed of a third material on the second layer;
forming the top portion by patterning the third layer by a first etching process;
forming the stem portion by patterning the second layer by a second etching process; and
forming the bottom portion by patterning the first layer by a third etching process, and
an etching rate of the third material in the second etching process is lower than an etching rate of the second material in the second etching process.

2. The display device manufacturing method of claim 1, wherein
the first layer includes a first bottom layer formed of the first material and a second bottom layer formed of a conductive material different from the first material and overlapping with the first bottom layer.

3. The display device manufacturing method of claim 2, wherein
the second bottom layer is thicker than the first bottom layer.

4. The display device manufacturing method of claim 1, wherein
the third layer includes a first top layer formed of the third material and a second top layer formed of a material different from the third material and overlapping with the first top layer.

5. The display device manufacturing method of claim 4, wherein
one of the first top layer and the second top layer has conductive property and the other has insulation property.

6. The display device manufacturing method of claim 2, wherein
the third layer includes a first top layer formed of the first material and a second top layer formed of a material different from the first material and overlapping with the first top layer.

7. The display device manufacturing method of claim 1, further comprising:
forming an organic layer covering the lower electrode and emitting light in response to application of a voltage; and
forming an upper electrode covering the organic layer and contacting the bottom portion.

8. The display device manufacturing method of claim 7, further comprising:
forming a sealing layer continuously covering a thin film, which includes the organic layer and the upper electrode, and the partition.

9. A display device manufacturing method, comprising:
forming a lower electrode;
forming a rib covering at least a part of the lower electrode; and
forming a partition on the rib, the partition including a conductive bottom portion, an insulating stem portion located on the bottom portion, and a top portion located on the stem portion and protruding relative to side surfaces of the stem portion, wherein
the formation of the partition includes:
forming a first layer including a layer formed of a conductive first material;
forming a second layer including a layer formed of an insulating second material on the first layer;
forming a third layer including a layer formed of a third material on the second layer;
forming the top portion by patterning the third layer by a first etching process;
forming the stem portion by patterning the second layer by a second etching process; and
forming the bottom portion by patterning the first layer by a third etching process, and
an etching rate of the third material in the third etching process is lower than an etching rate of the first material in the third etching process.

10. The display device manufacturing method of claim 9, wherein
the first layer includes a first bottom layer formed of the first material and a second bottom layer formed of a conductive material different from the first material and overlapping with the first bottom layer.

11. The display device manufacturing method of claim 10, wherein
the second bottom layer is thicker than the first bottom layer.

12. The display device manufacturing method of claim 9, wherein
the third layer includes a first top layer formed of the third material and a second top layer formed of a material different from the third material and overlapping with the first top layer.

13. The display device manufacturing method of claim 12, wherein
one of the first top layer and the second top layer has conductive property and the other has insulation property.

14. The display device manufacturing method of claim 10, wherein
the third layer includes a first top layer formed of the first material and a second top layer formed of a material different from the first material and overlapping with the first top layer.

15. The display device manufacturing method of claim 9, further comprising:
forming an organic layer covering the lower electrode and emitting light in response to application of a voltage; and
forming an upper electrode covering the organic layer and contacting the bottom portion.

16. The display device manufacturing method of claim 15, further comprising:
forming a sealing layer continuously covering a thin film, which includes the organic layer and the upper electrode, and the partition.

17. A display device manufacturing method, comprising:
forming a lower electrode;
forming a rib covering at least a part of the lower electrode; and
forming a partition on the rib, the partition including a conductive bottom portion, an insulating stem portion located on the bottom portion, and a top portion located on the stem portion and protruding relative to side surfaces of the stem portion, wherein
the formation of the partition includes:
forming a first layer including a layer formed of a conductive first material;
forming a second layer including a layer formed of an insulating second material on the first layer;
forming a third layer including a layer formed of the first material on the second layer;
forming the top portion by patterning the third layer by a first etching process;
forming the stem portion by patterning the second layer by a second etching process; and
forming the bottom portion by patterning the first layer by a third etching process, and
the layer formed of the first material included in the third layer is formed to be thicker than the layer formed of the first material included in the first layer.

18. The display device manufacturing method of claim 17, wherein
the first layer includes a first bottom layer formed of the first material and a second bottom layer formed of a conductive material different from the first material and overlapping with the first bottom layer.

19. The display device manufacturing method of claim 18, wherein
the second bottom layer is thicker than the first bottom layer.

20. The display device manufacturing method of claim 17, further comprising:
forming an organic layer covering the lower electrode and emitting light in response to application of a voltage; and
forming an upper electrode covering the organic layer and contacting the bottom portion.
